(19) United States
(12) Patent Application Publication
(10) Pub. No.: US 2016/0266198 A1
(43) Pub. Date: Sep. 15, 2016

(54) METHOD FOR IC TESTING BIGDATA ANALYSIS OPTION VALUE ANALYSIS

(71) Applicant: KWUN JONG CHEN, HSINCHU CITY 300 (TW)

(72) Inventor: KWUN JONG CHEN, HSINCHU CITY 300 (TW)

(21) Appl. No.: 15/162,925

(22) Filed: May 24, 2016

Related U.S. Application Data
(63) Continuation-in-part of application No. 14/486,002, filed on Sep. 15, 2014.

(51) Int. Cl. G01R 31/28; G06F 17/30

(52) U.S. Cl. CPC G01R 31/2851; G06F 17/30333

(57) ABSTRACT

A method for IC testing bigdata analysis and option value analysis includes: dividing a wafer into devices under test to undergo an electrical property test, retrieving data detected of the devices under test at different parameters; sorting specific parameters from different parameters according to an intended analysis result; loading a drawing software into a program, defining three-dimensional spatial coordinates, and producing a parameter location map of a three-dimensional cylindrical perspective graphic in three-dimensional spatial coordinates according to coordinate points X, Y, Z.

### REFERENCE TO RELATED APPLICATIONS

This Application is being filed as a Continuation-in-Part Application of Ser. No. 14/486,002, filed 15 Sep. 2014, currently pending.

### BACKGROUND OF THE INVENTION

1. Field of the Invention

The present invention relates to a semiconductor manufacturing process, and more particular to a method for IC testing bigdata analysis and option value analysis.

2. Description of the Prior Art

In the process of wafer test, the yield of a device under test (DUT) is not only influenced by individual problems of the process but also influenced by the other factors such as problems of testing machine. The problems of testing machine include improper correction of a test probe of the testing machine or improper testing parameter of the program of the testing machine, which would influence the yield of the device under test. In case the quality control process cannot analyze failure problem of the device under test caused by the individual problems of the process or the testing machine, the failure problem of the device under test cannot be solved. Moreover, the testing information of passed device under test cannot be traced. If the final product needs to be corrected, the correlated data is unavailable.

In another aspect, when a wafer test is done, the test result is usually presented in the form of a category report. Each wafer requires a report. Take an 8-inch wafer as an example, it contains thousands to ten thousand of dies (i.e., the aforesaid device under test (DUT)). The quantity of parameters of each die to be tested depends on customer needs. Lots of data-related techniques entail loading the reports into Excel of Windows Office to create a table with columns and rows crossing one another. The columns contains sequences of all the dies on the wafer. The rows contains sequences of various data of each die under test. Hence, expectedly, the Excel table has thousands to ten thousand of columns and dozens to hundreds of rows. There is never just one and only one wafer under test. If resultant big data is shown in the Excel table, the Excel table will contains too many numbers to be comprehensible and effective in yielding an analysis result of values, not to mention that the Excel table will be useless for later analysis and application.

### SUMMARY OF THE INVENTION

An object of the present invention is to provide a method for IC testing bigdata analysis and option value analysis, retrieve different parameters of each device under test of a wafer, and thus draw a parameter location map for a coordinate point Z in three-dimensional spatial coordinates according to data pertaining to specific parameters and coordinate points X, Y corresponding to the devices under test. The parameter location map exhibits intended items as needed, to yield therefrom an analysis result of values for subsequent analysis and application.

To achieve the above and other objects, a wafer test data analysis method, comprising the steps of:

obtaining data: dividing a test wafer into a plurality of test chips, each of the test chips being tested for electrical property and captured data under various parameters;

sorting parameter: a specific parameter being sorted from the various parameters according to a requirement of an analysis result;

defining three-dimensional space coordinates: compiling a program, defining a three-dimensional space coordinate in the program, comprising an X-coordinate axis, a Y-coordinate axis, and a Z-coordinate axis, wherein the X-coordinate axis and the Y-coordinate axis represent locations of the plurality of devices under test on the wafer, whereas the Z-coordinate axis represents the specific parameter;

analyzing the specific parameter: in the program, calculating and analyzing all the specific parameters of the plurality of devices under test, so as to generate a plurality of reference values corresponding to the specific parameters;

drawing three-dimensional parameter location map: loading the program and the plurality of reference values into a drawing software, and producing a parameter location map of a three-dimensional cylindrical perspective graphic according to a plurality of coordinate points X, Y, Z; wherein physical locations of the plurality of devices under test on the wafer are formed at graduations of the X-coordinate axis and the Y-coordinate axis, and, given the locations of the devices under test with respect to the graduations of the X-coordinate axis and the Y-coordinate axis, a three-dimensional cylindrical perspective graphic corresponding to the specific parameter is formed on the Z-coordinate axis according to the reference values thus obtained;

wherein, with the parameter location map, it is feasible to dynamically rotate the X-coordinate axis, the Y-coordinate axis and the Z-coordinate axis to achieve different angles of view, and the three-dimensional cylindrical perspective graphic formed on the Z-coordinate axis displays difference in color to discern the specific parameters attributed to the devices under test.

### BRIEF DESCRIPTION OF THE DRAWINGS

FIG. 1 is a three-dimensional parameter location map with respect to the current from the electrical property test of each test chip;

FIG. 2 is a partial enlarged view of grayscale of devices under test after the parameter location map (Paloc-Map) of FIG. 1 has been tested again;

FIG. 3 is a plan of grayscale of devices under test after the parameter location map (Paloc-Map) of FIG. 1 has been tested again;

FIG. 4 is another three-dimensional parameter location map with respect to the electric frequency from the electrical property test of each test chip;

FIG. 5 is a parameter location map (Paloc-Map) in which a parameter is set to a frequency generated by an electrical property test conducted after the devices under test of the present invention have been corrected;

FIG. 6 is another three-dimensional parameter location map with respect to the accumulative count of failed test chips at the same coordinate point (X, Y);

FIG. 7 is a parameter location map (Paloc-Map) with respect to the accumulative count of passed test chips at the same coordinate point (X, Y);

FIG. 8 is a parameter location map (Paloc-Map) for a plurality of wafers under a specific grade;

FIG. 9 is a plan of the parameter location map (Paloc-Map) of FIG. 8;

FIG. 10 is a parameter location map (Paloc-Map) for a plurality of wafers under another specific grade according to the present invention;

FIG. 11 is a parameter location map for exemplary purposes;

FIG. 12 is the parameter location map (Paloc-Map) of FIG. 11 at a different angle of view;

FIG. 13 is a partial enlarged view of the parameter location map (Paloc-Map) of FIG. 11;

FIG. 14 is another partial enlarged view of the parameter location map (Paloc-Map) of FIG. 11;

FIG. 15 is a parameter location map (Paloc-Map) defined with a specific parameter and adapted to observe its overall arrangement tendency and grayscale;

FIG. 16 is a plan of the parameter location map (Paloc-Map) of FIG. 15;

FIG. 17 is a parameter location map (Paloc-Map) of a concentric round target-like shape;

FIG. 18 is a plan of the parameter location map (Paloc-Map) of FIG. 17;

FIG. 19 is a parameter location map (Paloc-Map) after a grinding process has been performed on a probe;

FIG. 20 is a plan of the parameter location map (Paloc-Map) of FIG. 19;

FIG. 21 is another parameter location map (Paloc-Map) after a grinding process has been performed on a probe;

FIG. 22 is a parameter location map (Paloc-Map) which shows uniform distribution of specific parameters for a wafer test; and

FIG. 23 is a partial enlarged view of FIG. 22.

### DETAILED DESCRIPTION OF THE PREFERRED EMBODIMENTS

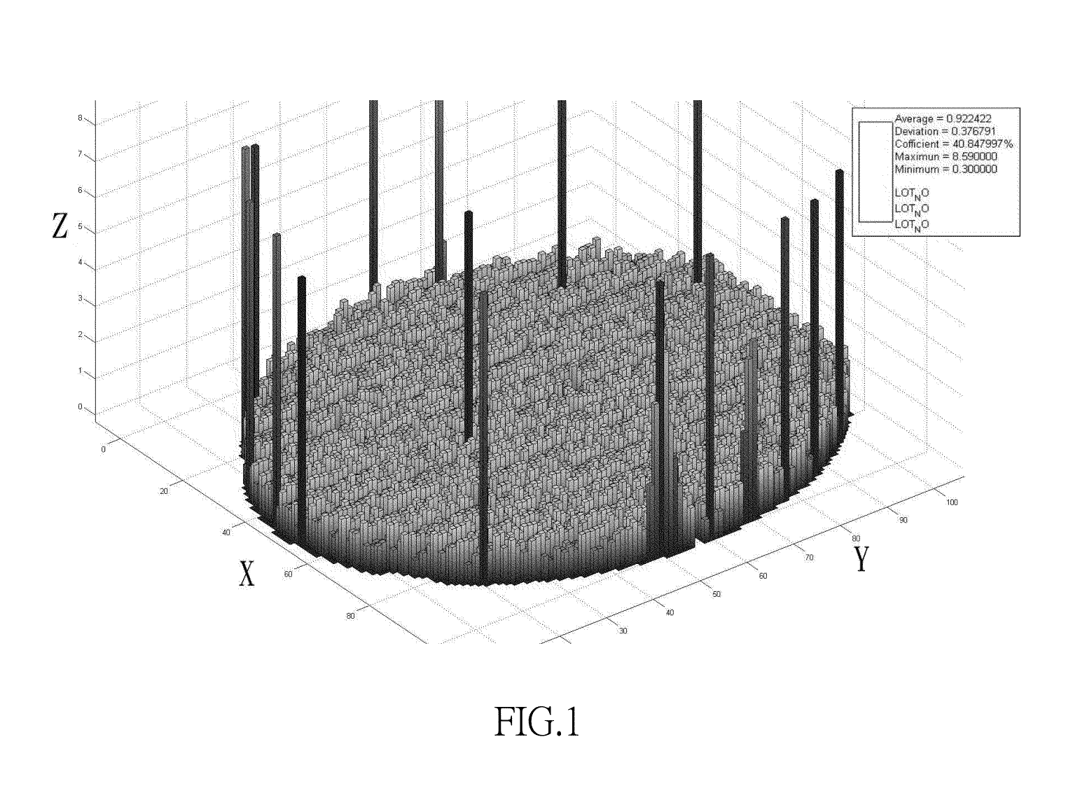

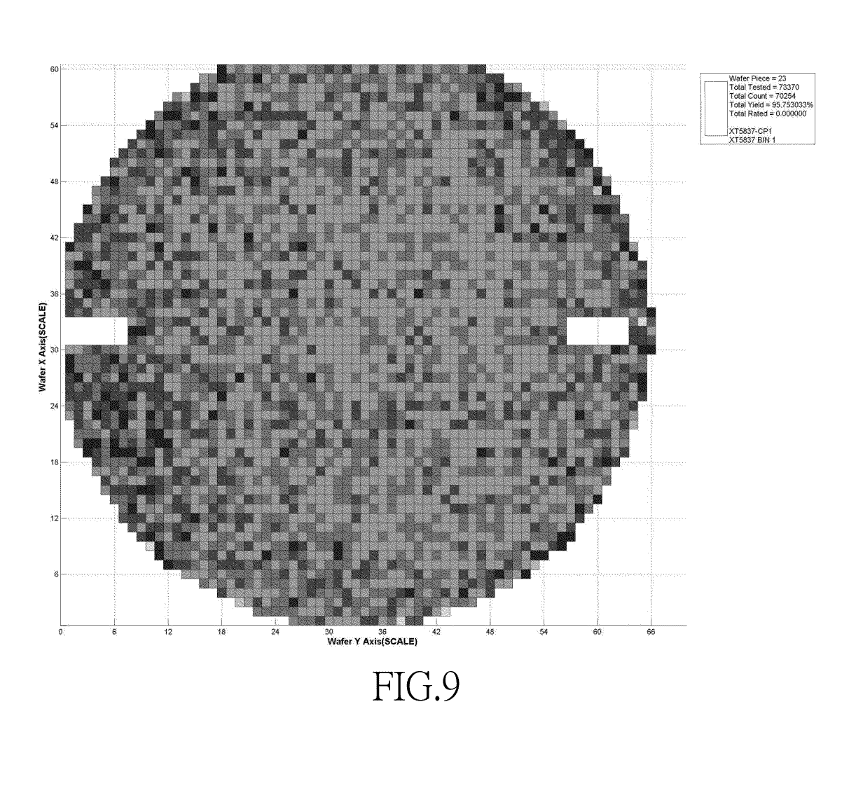

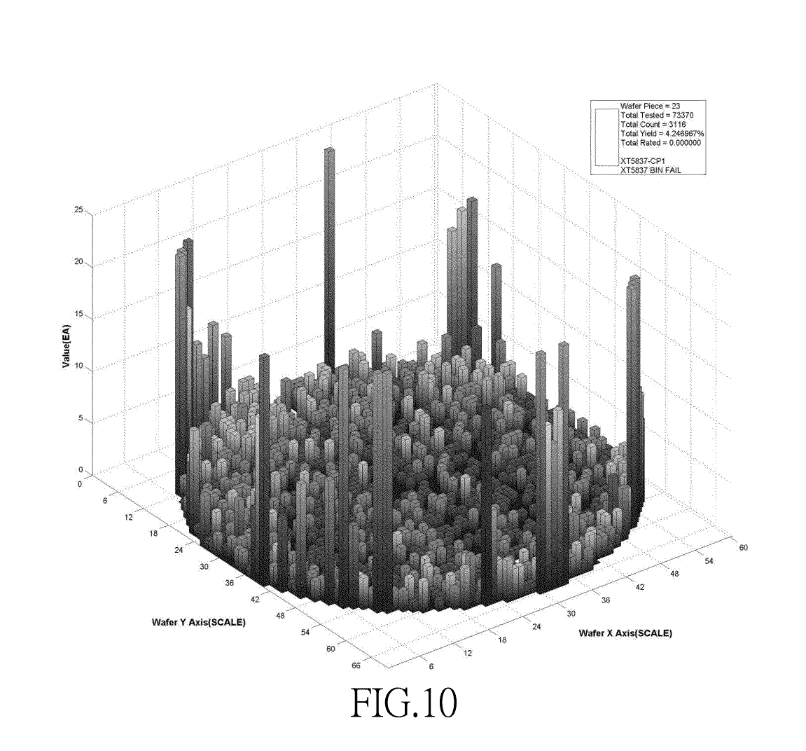

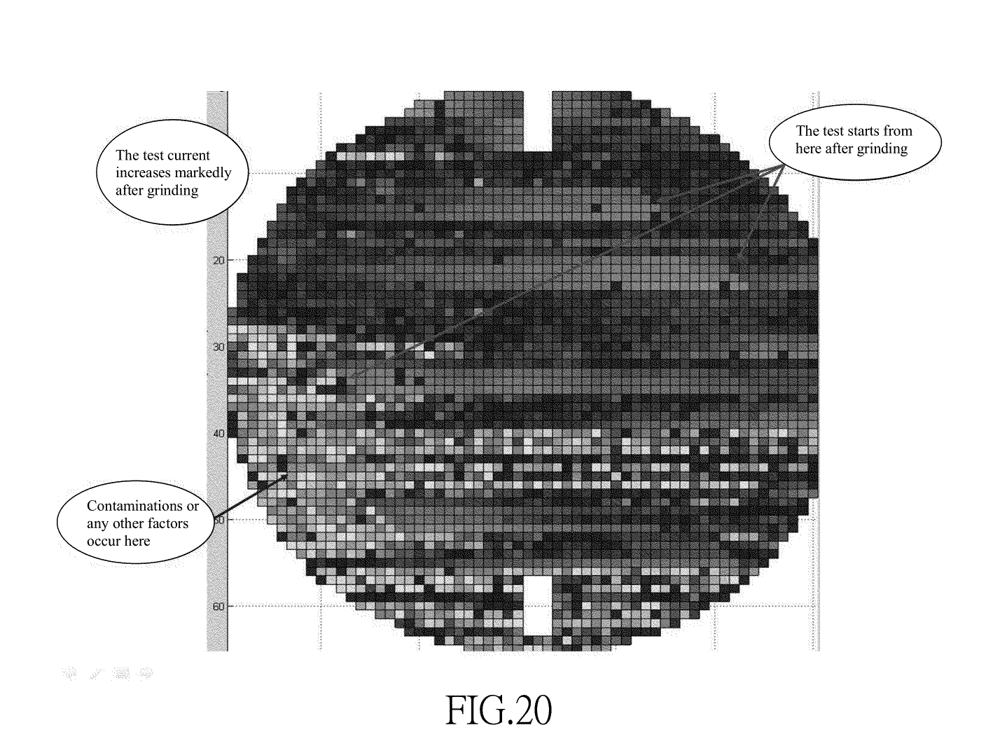

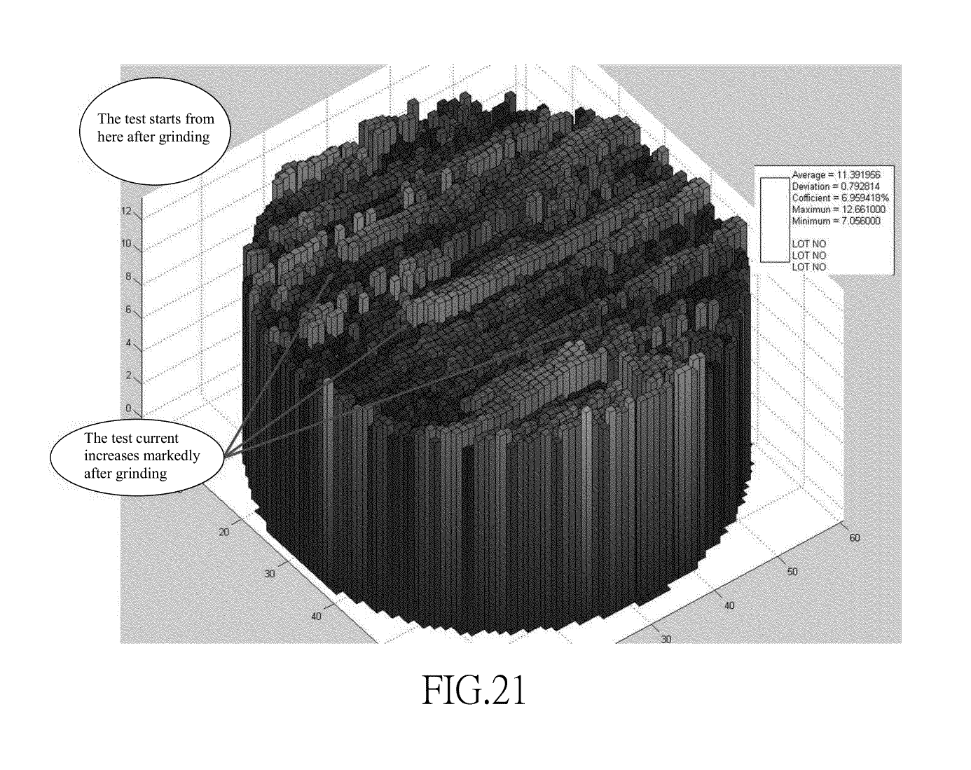

Referring to FIGS. 1-23, embodiments of the present inventions are illustrative rather than restrictive of the present invention.

In this embodiment, a method for IC testing bigdata analysis and option value analysis, comprising:

Obtaining data: dividing a test wafer into a plurality of test chips; each of the test chips is tested for electrical property and captured data under various parameters.

Sorting parameter: a specific parameter is sorted from the various parameters according to a requirement of an analysis result.

defining three-dimensional space coordinates: compiling a program, defining a three-dimensional space coordinate in the program, comprising an X-coordinate axis, a Y-coordinate axis, and a Z-coordinate axis, wherein the X-coordinate axis and the Y-coordinate axis represent locations of the plurality of devices under test on the wafer, whereas the Z-coordinate axis represents the specific parameter;

analyzing the specific parameter: in the program, calculating and analyzing all the specific parameters of the plurality of devices under test, so as to generate a plurality of reference values corresponding to the specific parameters;

Drawing three-dimensional parameter location map: loading the program and the plurality of reference values into a drawing software, a parameter location map of a three-dimensional cylindrical perspective graphic is created according to a plurality of coordinate points X, Y, Z; wherein physical locations of the plurality of devices under test on the wafer are formed at graduations of the X-coordinate axis and the Y-coordinate axis, and, given the locations of the devices under test with respect to the graduations of the X-coordinate axis and the Y-coordinate axis, a three-dimensional cylindrical perspective graphic corresponding to the specific parameter is formed on the Z-coordinate axis according to the reference values thus obtained;

wherein, with the parameter location map, it is feasible to dynamically rotate the X-coordinate axis, the Y-coordinate axis and the Z-coordinate axis to achieve different angles of view, and the three-dimensional cylindrical perspective graphic formed on the Z-coordinate axis displays difference in color to discern the specific parameters attributed to the devices under test.

The aforesaid difference in color arises from different colors (such as red, yellow, blue and the like) or grayscale (such as crimson and blush).

In this embodiment, with a computer device, the three-dimensional spatial coordinates are for use in executing the program with the drawing software and performing data conversion on the devices under test according to a position of the wafer and a specific parameter, wherein X, Y denote horizontal coordinates, and Z denotes a vertical coordinate, using the horizontal coordinates to define coordinate points X, Y of the devices under test, using the vertical coordinate to define data of the specific parameters as coordinate point Z, wherein, in the three-dimensional spatial coordinates, the parameter location map is produced according to the coordinate points X, Y, Z corresponding to each said device under test. In this embodiment, the drawing software is MATrix LABoratory (Matlab).

Referring to FIG. 1, it is a parameter location map drawn according to the method for IC testing bigdata analysis and option value analysis, also using a single wafer as a test subject. As shown in FIG. 1, the devices under test of the wafer are each defined with a coordinate point X, Y. In the parameter location map, the specific parameter is exemplified by the current generated by each device under test during an electrical property test. The program compilation is as follows:

/* Parameter Location map (Paloc_map), Filename.anc */
Analysis_PARAMETER_POSITION_CHART
PARAMETER_POSITION_1(″ISB_3V(uA)″)
{

| | |
|---|---|
| x_axial_int; | /* X-axis graduations are integers */ |
| y_axial_int; | /* Y-axis graduations are integers */ |

Z_axial_doublefloat from −0.3 to 3 step 0.01; /* Z-axis graduations are float */

| | |
|---|---|
| x_unit SCALE; | /* X-axis units are graduations */ |
| y_unit SCALE; | /* Y-axis units are graduations */ |
| z_unit UA; | /* Z-axis units are in microampere(μA) */ |

| | |
|---|---|
| CAL_Average; | /* calculate the average of specific parameters */ |
| CAL_Deviation; | /* calculate the average of specific parameters */ |
| CAL_Cofficient; | /* calculate the variance of specific parameters */ |
| CAL_Maximun; | /* identify the maximum of specific parameters */ |
| CAL_Minimun; | /* identify the minimum of specific parameters */ |
| CAL_Mode; | /* identify the mode of specific parameters */ |
| CAL_Mode_Cnt; | /* identify the number of specific parameters */ |
| CAL_Median; | /* identify the median of specific parameters */ |

| | |
|---|---|
| CAL_Range; | /* identify the range of specific parameters calculated */ |

```
  CAL_Skewness; /* calculate the coefficient of skewness of specific parameters */
  CAL_Kurtosis; /* calculate the coefficient of kurtosis of specific parameters */
```

| | |
|---|---|
| des_1(″XT5837-CP1″); | /* directly list the text-1” XT5837-CP1” */ |

| | |
|---|---|
| des_2(″ISB 3V(uA)″); | /* directly list the text-2” ISB 3V(uA)” */ |

| | |
|---|---|
| Drawing_view(1,−146,45); | /* Drawing_view(type,az,el); taking pictures */ |

```
  Drawing_view(1,270,90);
  Drawing_view(1,145,30);
```

}END;

TABLE 1

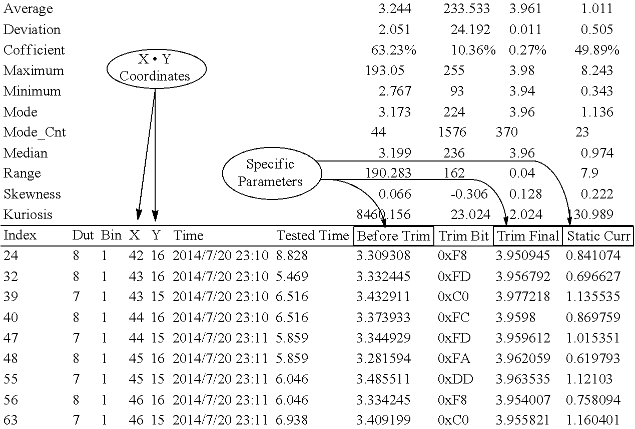

Table 1 shows the specific parameters (currents) to be tested and X, Y coordinates.

In this embodiment, as indicated by the program, the step of analyzing the specific parameter entails calculating the average of specific parameters, calculating the variance of specific parameters, identifying the maximum of specific parameters, identifying the minimum of specific parameters, identifying the mode of specific parameters, identifying the number of specific parameters, identifying the median of specific parameters, identifying the range of specific parameters calculated, calculating the coefficient of skewness of specific parameters, and calculating the coefficient of kurtosis of specific parameters, with reference to the plurality of reference values.

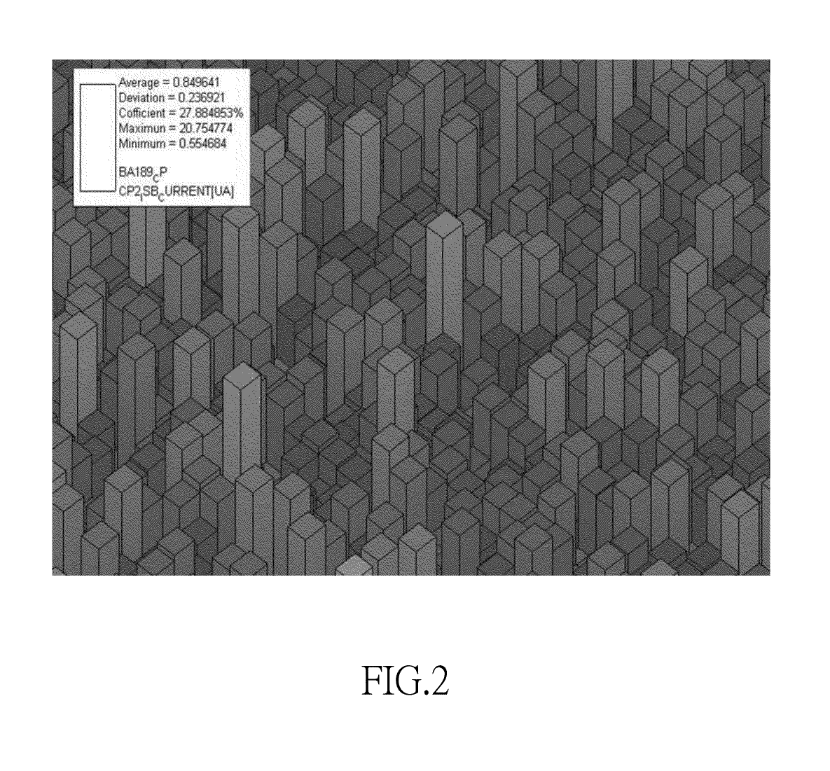

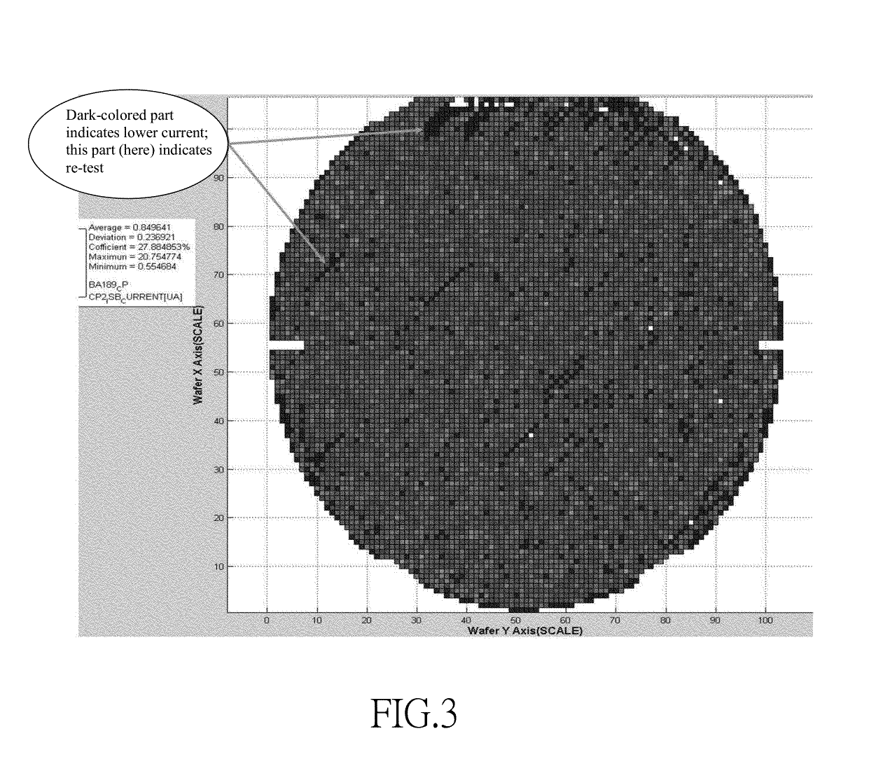

The data pertaining to current generated by the devices under test during an electrical property test is regarded as each coordinate point Z. The difference in the current is expressed by grayscale or different colors when the specific parameters are currents and are presented in the parameter location map. Referring to FIGS. 2, 3, after a retest, the grayscale of each device under test is effective in determining quickly that a deep color represents a low current. The low current is distributed in the form of regular equidistant skew arrangement so that a test technician quickly infers an error in the testing position of the probe and thus recognizes a need to configure test program software anew.

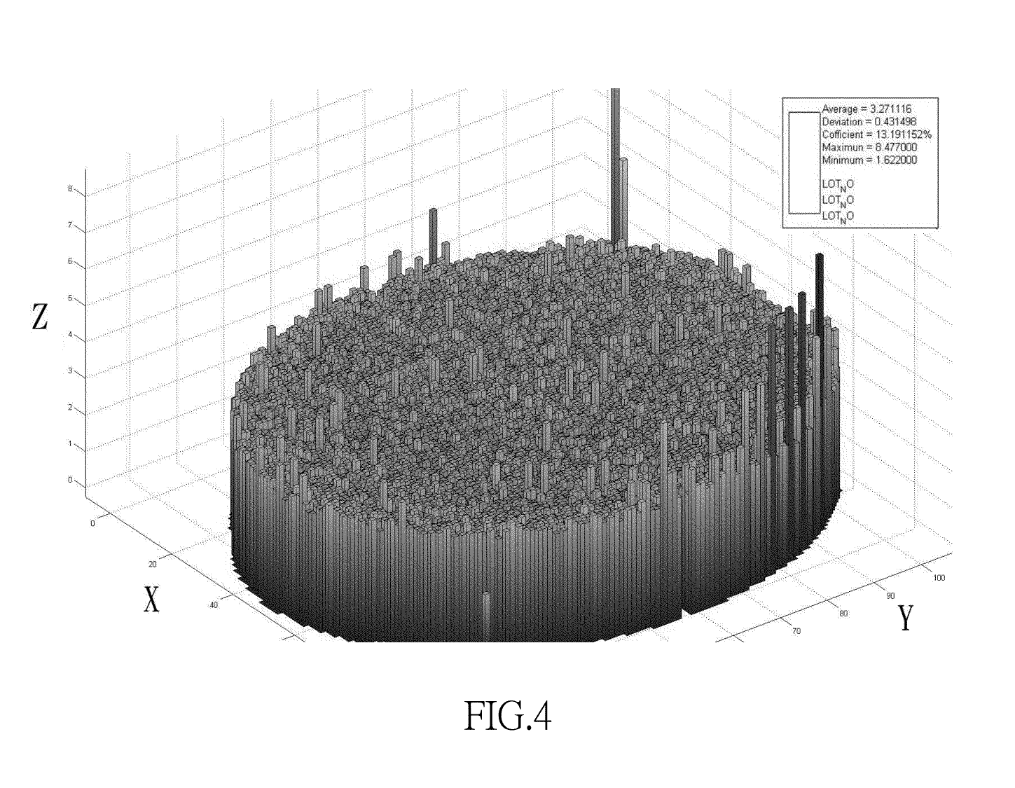

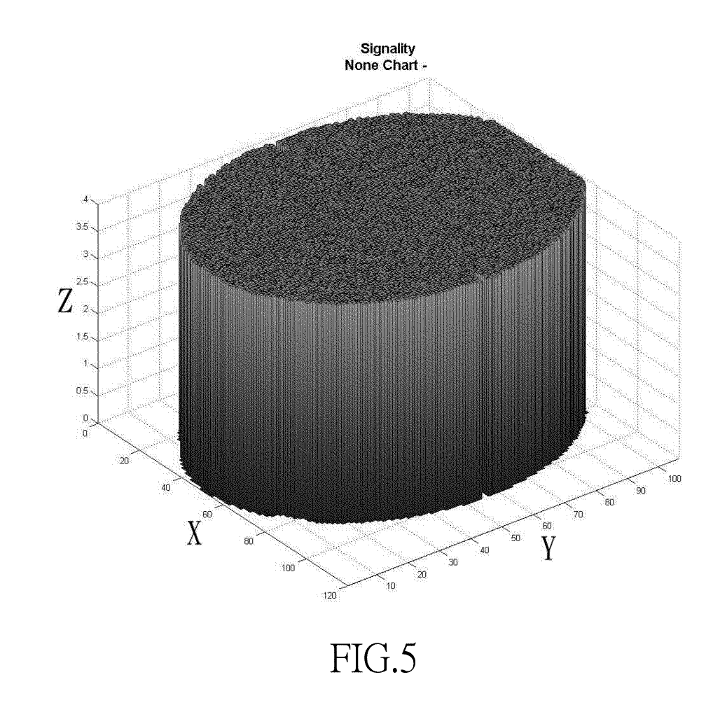

Referring to FIG. 4, there is shown another parameter location map produced according to the method for IC testing bigdata analysis and option value analysis, wherein a single wafer is the test subject. As shown in the diagram, devices under test of the wafer are each defined with a coordinate point X, Y, and the specific parameters used in the parameter location map are frequencies generated by the devices under test during an electrical property test. The program compiled is the same as the aforesaid program where the specific parameters are currents except that the specific parameters for use in the program are frequencies rather than currents. In an embodiment where the specific parameters are frequencies, the data pertaining to frequency generated by the devices under test during an electrical property test is regarded as each coordinate point Z. The difference in the frequency is expressed by grayscale or different colors when the specific parameters are presented in the parameter location map. Referring to the three-dimensional parameter location map in FIG. 4, it is observed that variances appeared in the frequency generated from the electrical property test of each test chip, which needs to be corrected in the process. The three-dimensional parameter location map in FIG. 5 shows the data of the frequency from the electrical property test of each test chip after process correction. It is observed that the frequency of the electrical property of each test chip is closed with each other.

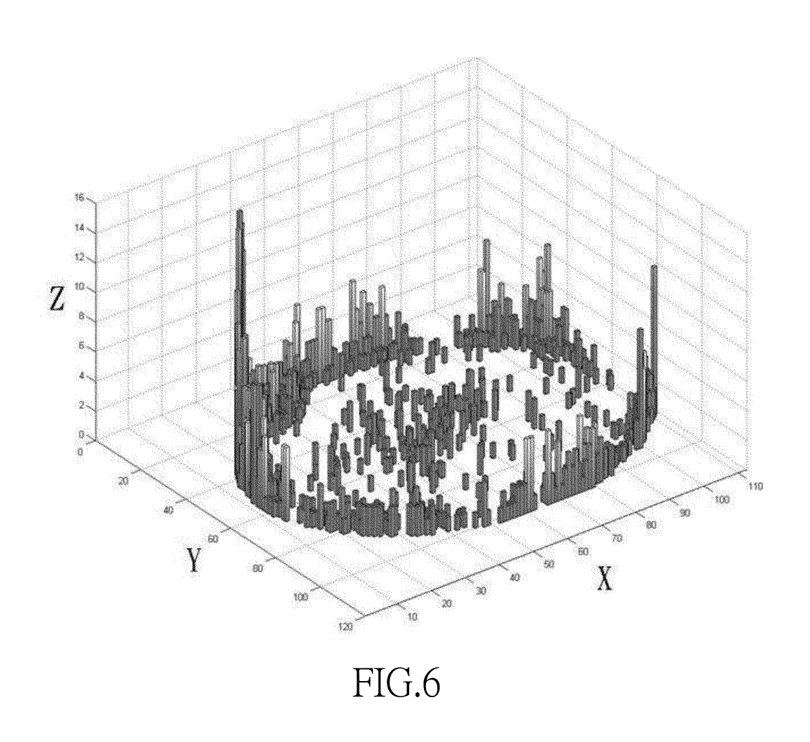

Referring to FIG. 6, there is shown yet another parameter location map produced according to the method for IC testing bigdata analysis and option value analysis, wherein a plurality of stacked wafers is used as test subjects. As shown in the diagram, devices under test of the wafers at the same coordinate X, Y are each defined with a coordinate point X, Y, and the specific parameters used in the parameter location map are accumulative counts of failed devices under test of the same coordinate X, Y during an electrical property test performed on the devices under test. The program compiled is the same as the aforesaid program where the specific parameters are currents except that the specific parameters for use in the program are accumulative counts of test failures rather than currents. In an embodiment where the specific parameters are accumulative counts of test failures, data pertaining to the accumulative counts of failed devices under test during an electrical property test conducted on the devices under test at the same coordinate X, Y is regarded as the coordinate point Z. The difference in the aforesaid numbers is expressed by grayscale or different colors when the specific parameters are presented in the parameter location map.

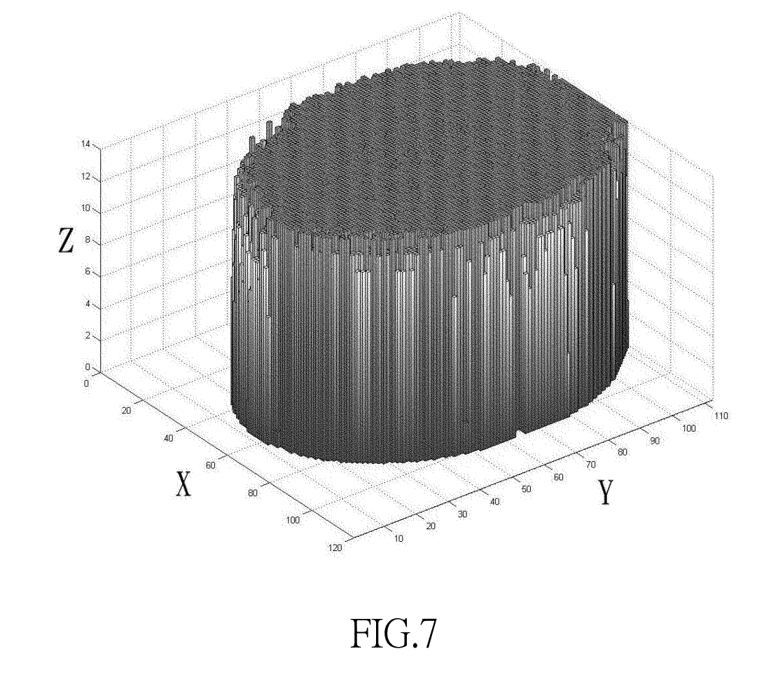

Referring to FIG. 7, there is shown yet another parameter location map produced according to the method for IC testing bigdata analysis and option value analysis, also using stacked wafers as test subjects. As shown in the diagram, devices under test of the wafers at the same coordinate X, Y are each defined with a coordinate point X, Y. In the parameter location map, the specific parameters are accumulative counts of passed devices under test during an electrical property test conducted on the devices under test at the same coordinate X, Y. The program compiled is the same as the aforesaid program where the specific parameters are currents except that the specific parameters for use in the program are accumulative counts of test passes rather than currents. In an embodiment where the specific parameters are accumulative counts of test passes, data pertaining to accumulative counts passed devices under test during an electrical property test conducted on the devices under test at the same coordinate X, Y is regarded as coordinate points. The difference in the aforesaid numbers is expressed by grayscale or different colors when the specific parameters are presented in the parameter location map.

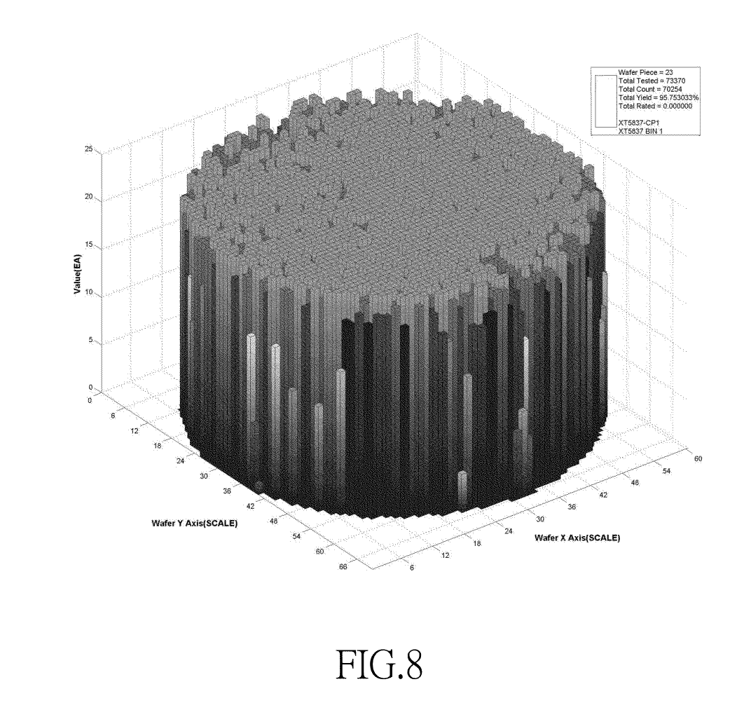

Referring to FIG. 8 through FIG. 10, there is shown another parameter location map which also uses a plurality of stacked wafers as test subjects. As shown in the diagrams, devices under test located at the same coordinate X,Y of the wafers are defined with a coordinate point X, Y. In this parameter location map, the specific parameters are exemplified by the Binning result of devices under test when the devices under test are located at the same coordinate X, Y during an electrical property test. The compilation of the program is as follows:

* Option Value 5 , BIN Stack Map, Filename.anb */
Analysis_BIN_STACK_CHART [FILENAME.ANB]
BIN_STACK_1A(″BIN 1″) // ONLY DISPLYA BIN_1
{

| | |
|---|---|
| x_unit SCALE; | /* X-axis units are graduations */ |
| y_unit SCALE; | /* Y-axis units are graduations */ |
| z_unit EA; | /* Z-axis units are numbers */ |

| | |
|---|---|
| BIN_SHOW NORMAL; | /* normal show, but not reverse show */ |

| | |
|---|---|
| BINDISPLAY 0X0001; | /* DISPLAT BIN 1~64 expressed in hexadecimal */ |

| | |
|---|---|
| CAL_TOTAL_WAFER_PICE; | /* Display Wafer Pice */ |
| CAL_TOTAL_TESTED; | /* Display Total Tested */ |

| | |
|---|---|
| CAL_TOTAL_COUNT; | /* Display Total Probe up/down Count */ |

| | |
|---|---|
| CAL_TOTAL_YIELD; | /* Display Bin 1 Yield Count */ |
| CAL_TOTAL_YIELD_RATE ; | /* Display Bin 1 Yield Rate */ |

| | |
|---|---|
| des_1(″XT5837-CP1″); | /* directly list the text-1” XT5837-CP1” */ |
| des_2(″XT5837 BIN 1″); | /* directly list the text-1” XT5837 BIN 1” */ |
| Drawing_view(1, −146,45); | /* Drawing_view(type,az,el); taking pictures */ |

```
  Drawing_view(1,270,90);
  Drawing_view(1,145,30);
}END;
```

TABLE 2

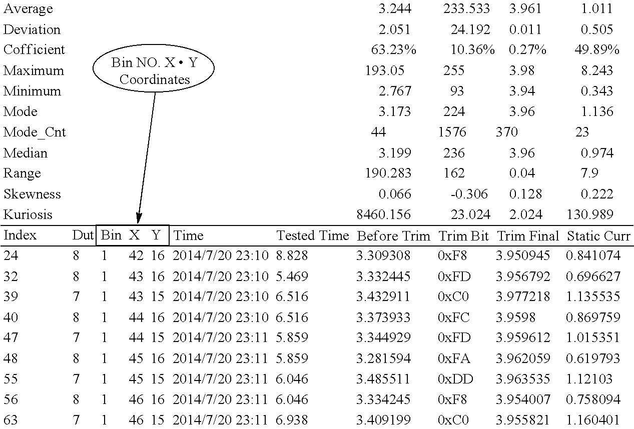

The specific parameter (Bin. NO) to be tested and X, Y coordinates are shown in Table 2 above.

In this embodiment, in the step of analyzing the specific parameter, the plurality of reference values, as indicated by the program, include Display Wafer Pice, Display Total Tested, Display Total Probe up/down Count, Display Bin 1 Yield Count, and Display Bin 1 Yield Rate.

In an embodiment where the specific parameters are accumulative counts of the Binning results, the data pertaining to the Binning results of the devices under test located at the same coordinate X, Y during an electrical property test conducted on the devices under test is regarded as coordinate point Z. The difference in the Binning results is expressed by grayscale or different colors when the specific parameters are presented in the parameter location map. Referring to FIG. 8 through FIG. 10, they are diagrams obtained according to Bin 1 of wafer stacked. Color levels indicative of quantity are shown on the right of FIG. 8, showing no unsatisfactory fixed device under test among the wafers but a little distribution of deep color at the periphery; hence, the test result is reasonable.

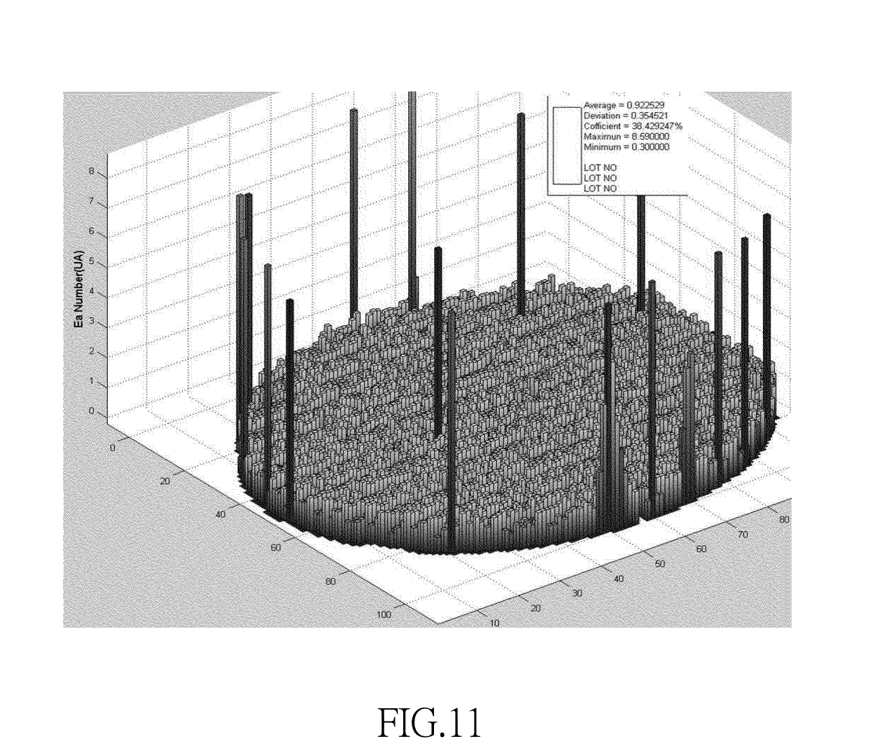

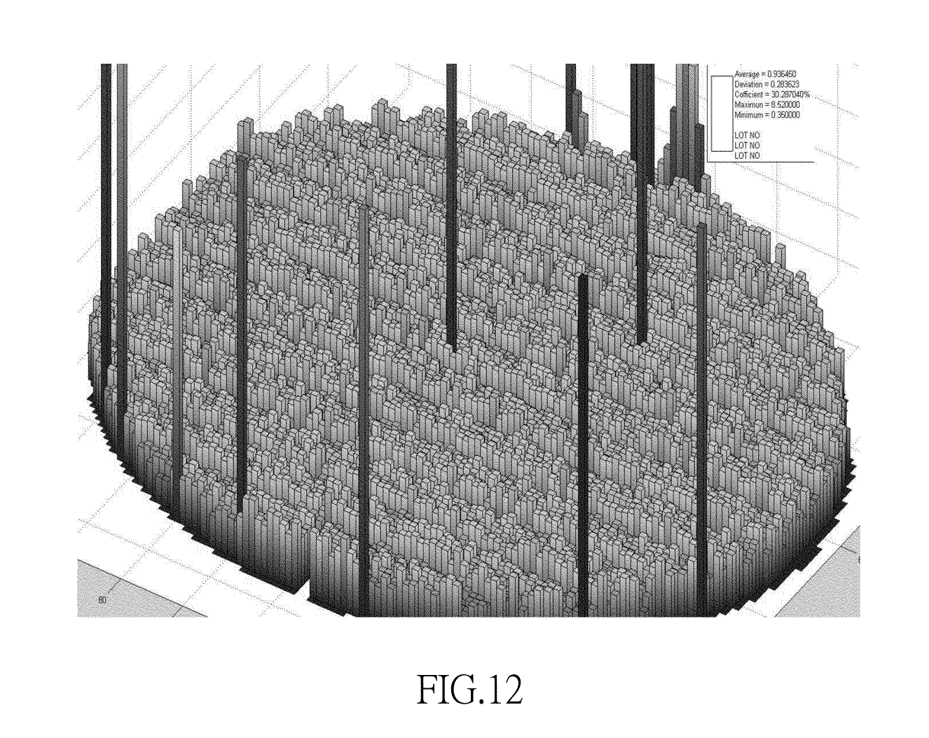

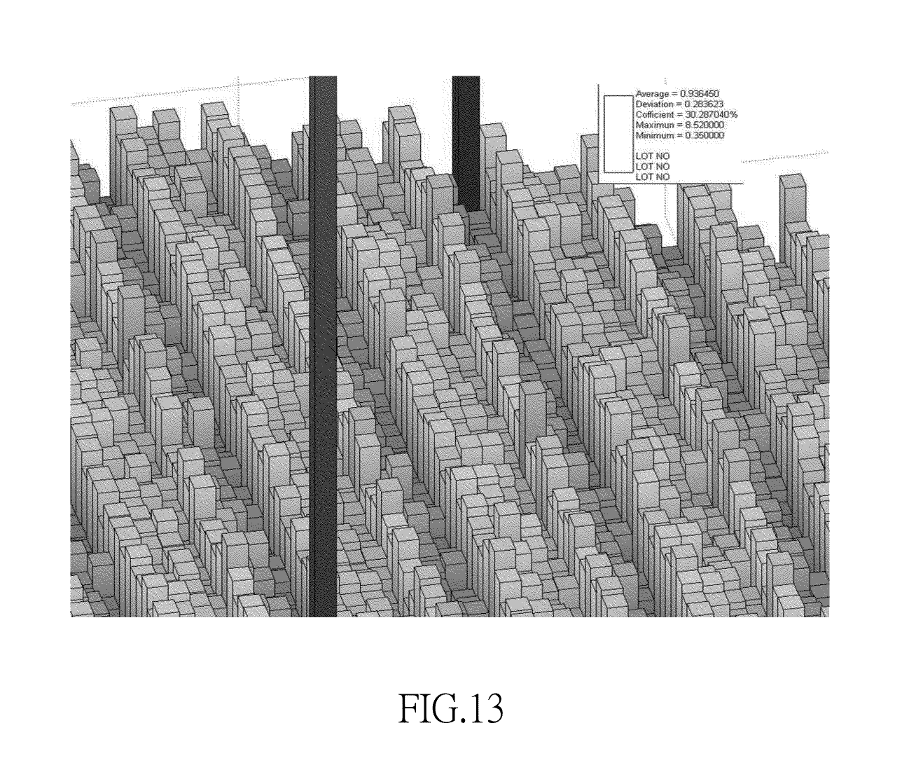

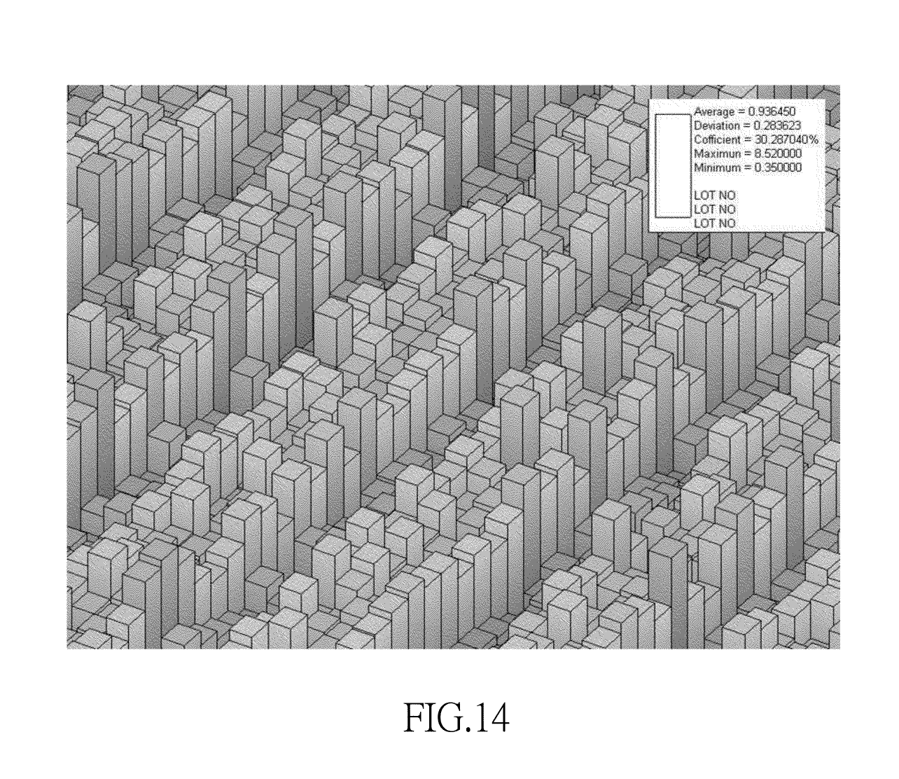

Referring to FIGS. 11, 12, with the parameter location map, the overall tendency of wafers can be observed and analyzed from different angles. Referring to FIGS. 13, 14, the parameter location map is enlarged and rotated in real time, for example, to exhibit three-dimensional cylindrical perspective graphics of Z-coordinate axis from different angles in a manner characterized by regular variations and a conspicuous cascade so that details are rendered clear, thereby enhancing reading precision.

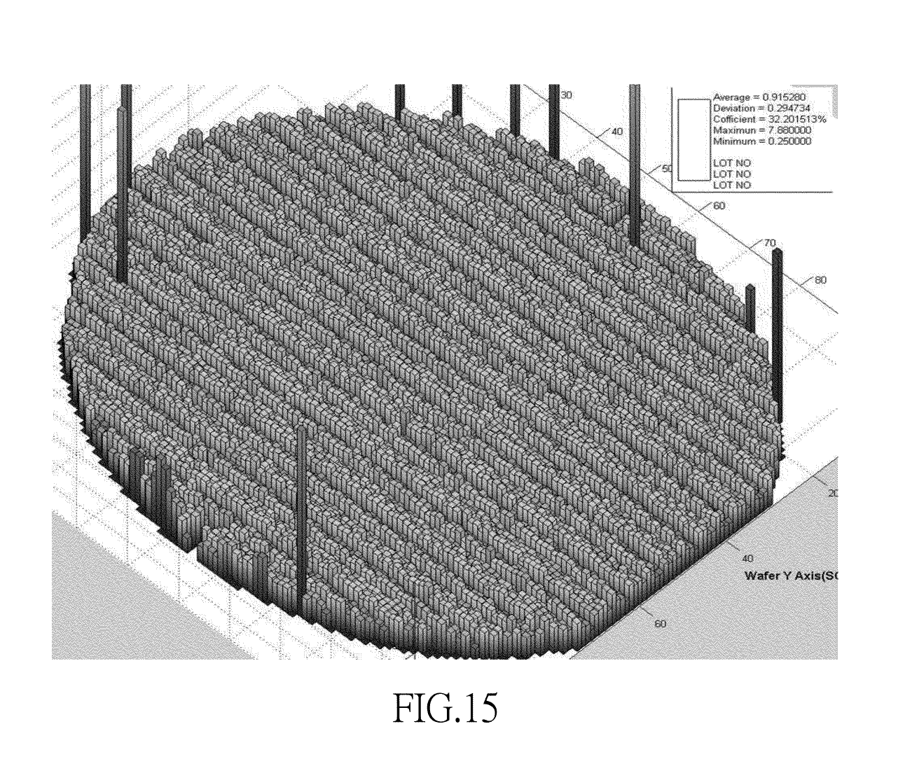

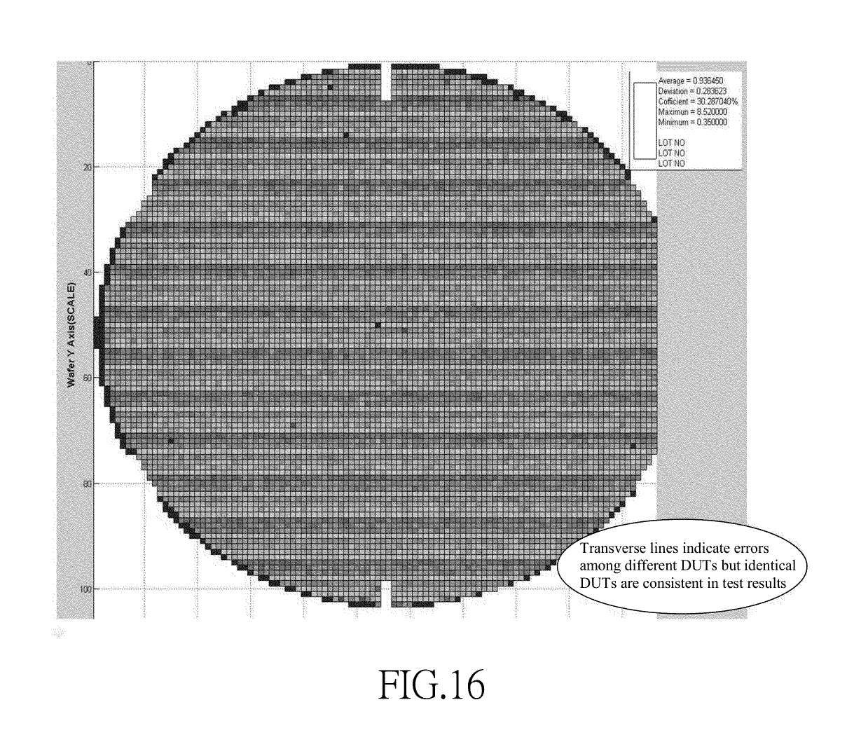

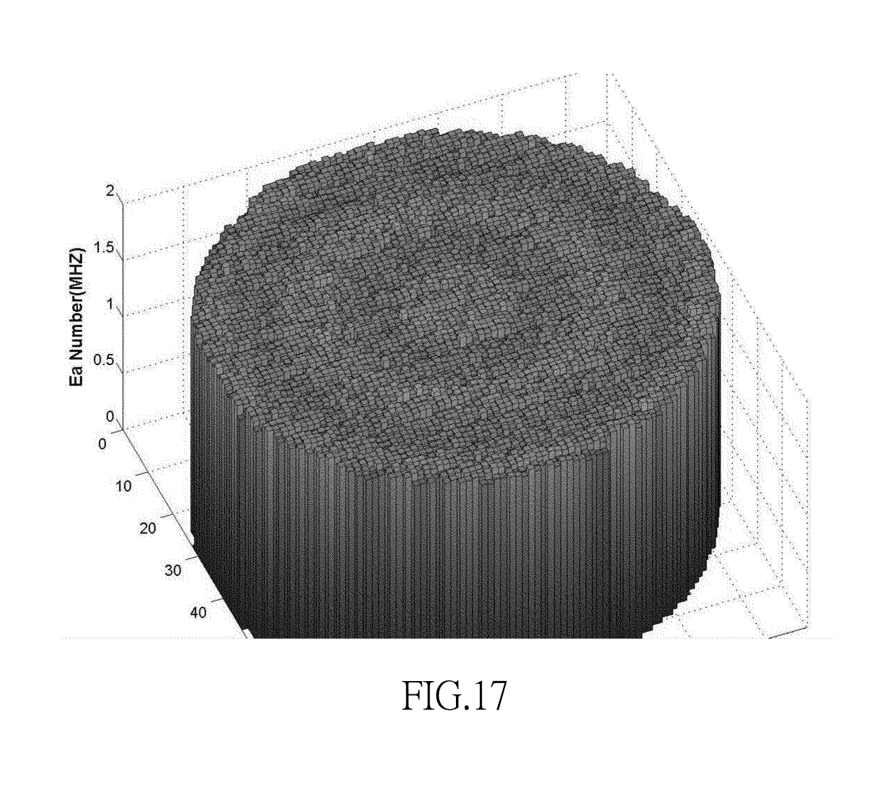

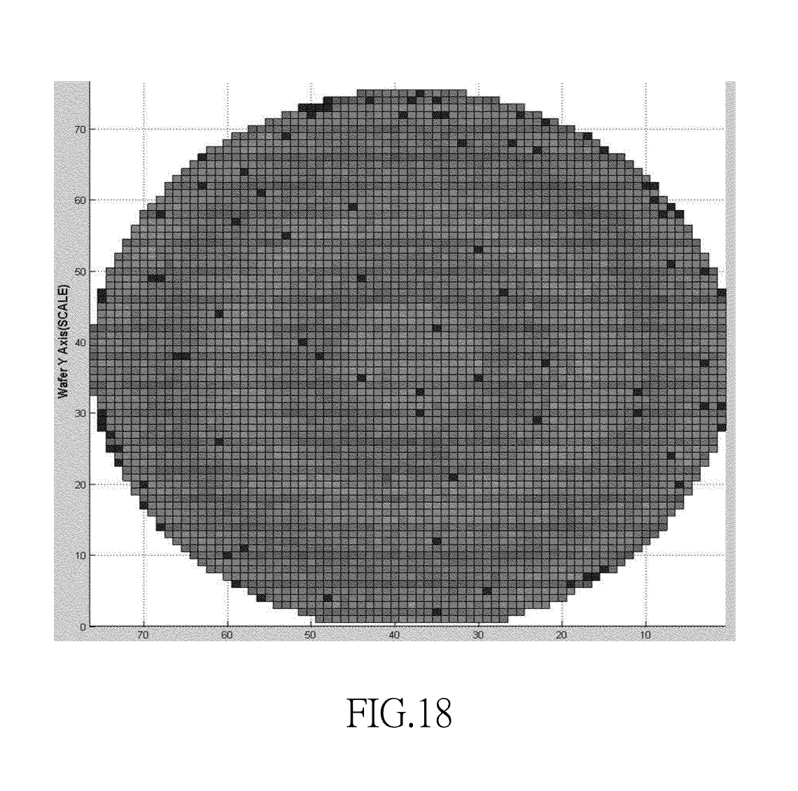

In addition to the presentation of the parameter location map (shown in FIGS. 15, 16), the specific parameters expressed on Z-coordinate axis are characterized in that grayscale or different colors are not only effective in discerning the difference in its overall arrangement tendency to therefore represent the difference in the specific parameters and express the strength or magnitude of the specific parameters but also allow a user to quickly determine whether devices under test fail for a reason attributed to a manufacturing process or a test machine Referring to FIGS. 17, 18, given grayscale or different colors, a concentric round target-like shape shown in the parameter location map indicates that the wafer manufacturing process is faulty and thus provides a solution to improve the manufacturing process.

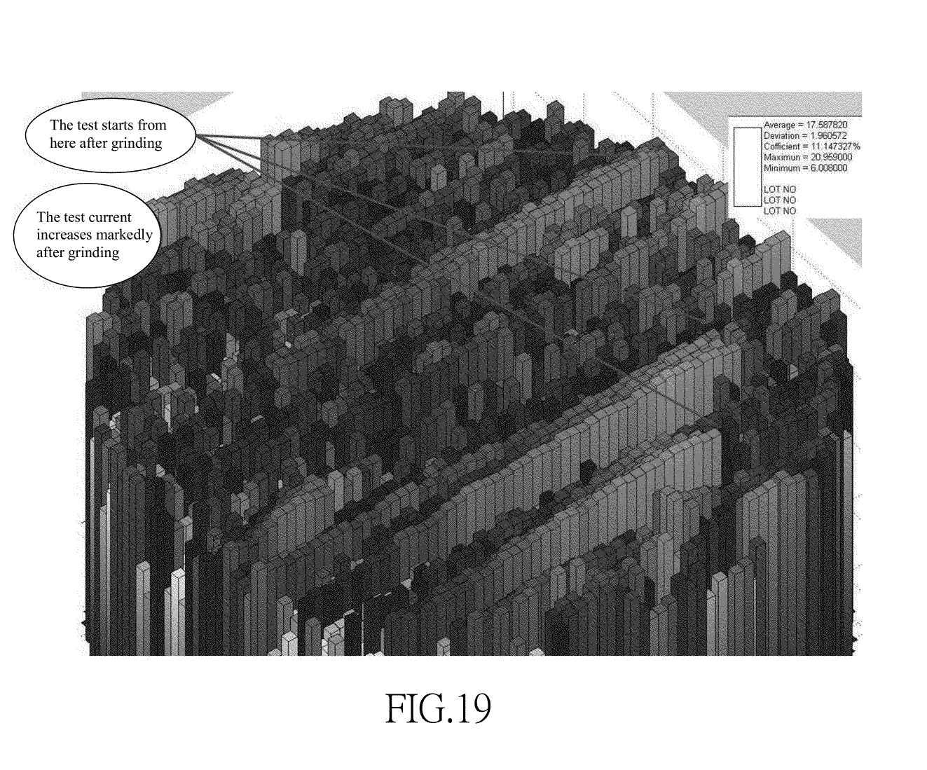

Referring to FIG. 19 through FIG. 21, if, after a grinding process has been performed on the probe during a test, its parameter location map still displays a wafer tendency of regular arrangement with transverse spacing, and the current decreases gradually in the direction from the point of the start of the test to the probe, it will be feasible to determine that a fault occurs to the wafer manufacturing process rather than the test machine (probe), and test technicians can determine whether the unsatisfactory devices under test are faulty for a reason attributed to the wafer foundry or the testing plant with reference to a related basis.

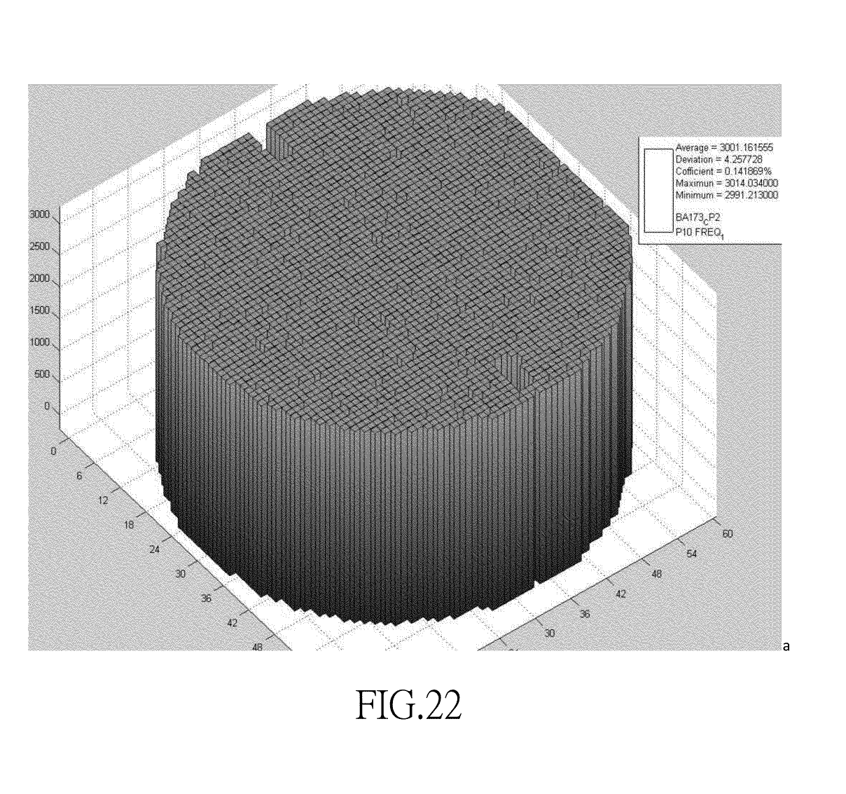

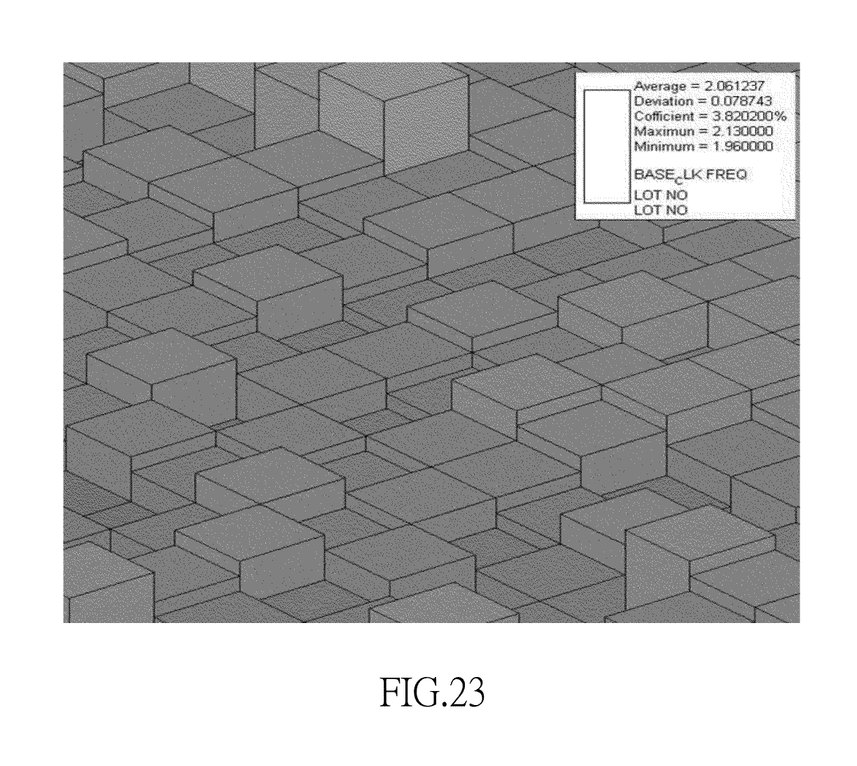

Referring to FIGS. 22, 23, the diagrams enable test technicians to perceive at a glance the uniform distribution of specific parameters for use in wafer testing, and can be enlarged (zoomed in) or rotated so that the test technicians and analysts can quickly determine that not only are test parameters randomly/regularly distributed but adjacent test parameters are also of no equal value; hence, the arrangement is reasonable, thereby allowing the test technicians and analysts to infer that the test result is normal.

The advantages of the present invention are described as following:

1. According to the aforementioned distribution map generated by the wafer test data analysis method for the data of test result, the accuracy of the data could be checked.

2. The aforementioned distribution map could be multi-batch drawn with respect to a plurality of wafers or single batch drawn with respect to single wafer.

3. The aforementioned distribution map could be calculated for median of standard deviation and variance of mean.

4. It is available to compare statistical parameters such as upper and lower limits of median and mean of standard deviation for quality control.

5. The trend of the test parameter could be observed.

6. According to the test results of the specific group of the test chips and comparing the statistical parameters of the test chip, the difference between every test chip could be observed.

What is claimed is:

1. A method for IC testing bigdata analysis and option value analysis, comprising the steps of:
obtaining data: dividing a test wafer into a plurality of test chips, each of the test chips being tested for electrical property and captured data under various parameters;
sorting parameter: a specific parameter being sorted from the various parameters according to a requirement of an analysis result;
defining three-dimensional space coordinates: compiling a program, defining a three-dimensional space coordinate in the program, comprising an X-coordinate axis, a Y-coordinate axis, and a Z-coordinate axis, wherein the X-coordinate axis and the Y-coordinate axis represent locations of the plurality of devices under test on the wafer, whereas the Z-coordinate axis represents the specific parameter;
analyzing the specific parameter: in the program, calculating and analyzing all the specific parameters of the plurality of devices under test, so as to generate a plurality of reference values corresponding to the specific parameters;
drawing a parameter location map: loading the program and the plurality of reference values into a drawing software, producing a parameter location map of a three-dimensional cylindrical perspective graphic according to a plurality of coordinate points X, Y, Z; wherein physical locations of the plurality of devices under test on the wafer are formed at graduations of the X-coordinate axis and the Y-coordinate axis, and, given the locations of the devices under test with respect to the graduations of the X-coordinate axis and the Y-coordinate axis, a three-dimensional cylindrical perspective graphic corresponding to the specific parameter is formed on the Z-coordinate axis according to the reference values thus obtained;
wherein, with the parameter location map, it is feasible to dynamically rotate the X-coordinate axis, the Y-coordinate axis and the Z-coordinate axis to achieve different angles of view, and the three-dimensional cylindrical perspective graphic formed on the Z-coordinate axis displays difference in color to discern the specific parameters attributed to the devices under test.

2. The method for IC testing bigdata analysis and option value analysis of claim 1, wherein, with a computer device, the three-dimensional spatial coordinates are for use in executing the program with the drawing software and performing data conversion on the devices under test according to a position of the wafer and a specific parameter, wherein X, Y denote horizontal coordinates, and Z denotes a vertical coordinate, using the horizontal coordinates to define coordinate points X, Y of the devices under test, using the vertical coordinate to define data of the specific parameters as coordinate point Z, wherein, in the three-dimensional spatial coordinates, the parameter location map is produced according to the coordinate points X, Y, Z of each said device under test.

3. The method for IC testing bigdata analysis and option value analysis of claim 2, wherein the specific parameter is a frequency generated by the devices under test during an electrical property test.

4. The method for IC testing bigdata analysis and option value analysis of claim 2, wherein the specific parameter is a current generated by the devices under test during an electrical property test.

5. The method for IC testing bigdata analysis and option value analysis of claim 2, wherein the specific parameter is an accumulative count of failed stacked wafers in the devices under test of the same coordinate X, Y.

6. The method for IC testing bigdata analysis and option value analysis of claim 2, wherein the specific parameter is an accumulative count of passed stacked wafers in the devices under test of the same coordinate X, Y.

7. The method for IC testing bigdata analysis and option value analysis of claim 2, wherein the specific parameter is a Binning result of the devices under test tested by different probes.
